(19) United States
(12) Patent Application Publication
(10) Pub. No.: US 2026/0173732 A1
(43) Pub. Date: Jun. 18, 2026

(54) DISPLAY DEVICE, ELECTRONIC DEVICE INCLUDING THE SAME, AND METHOD OF MANUFACTURING DISPLAY DEVICE

(71) Applicant: Samsung Display Co., Ltd., Yongin-Si (KR)

(72) Inventor: Intae SON, Yongin-si (KR)

(21) Appl. No.: 19/391,758

(22) Filed: Nov. 17, 2025

(30) Foreign Application Priority Data
Dec. 17, 2024 (KR) 10-2024-0188995

(51) Int. Cl. H10K 59/80; H10K 59/12; H10K 102/00

(52) U.S. Cl. CPC H10K 59/874; H10K 59/1201; H10K 59/871; H10K 2102/311; H10K 2102/351

(57) ABSTRACT

Disclosed is a display device including a display panel including a first area and a bending area adjacent to the first area, the bending area having a predetermined radius of curvature, a functional layer disposed on the display panel and overlaps the first area on a plane, and a bending protecting layer disposed on the display panel and wherein at least a portion of the bending protecting layer overlaps the bending area on a plane. The functional layer includes a main part overlapping the first area and a hydrophilic coating part disposed between the main part and the bending protecting layer. The at least a portion of the bending protecting layer is spaced a predetermined distance from the hydrophilic coating part.

### CROSS-REFERENCE TO RELATED APPLICATIONS

This application claims priority under 35 U.S.C. § 119 to Korean Patent Application No. 10-2024-0188995 filed on December 17, 2024, in the Korean Intellectual Property Office, the disclosures of which are incorporated by reference herein in their entireties.

### BACKGROUND

Embodiments of the present disclosure described herein relate to a display device, an electronic device including the same, and a method of manufacturing a display device, and more particularly, relate to a foldable display device and a method of manufacturing the display device.

A display device includes a display area activated according to an electrical signal. The display device may detect an input applied from the outside through the display area, and at the same time, display various images to provide information to a user. Recently, display devices having various shapes have been developed, and thus display areas having various shapes have been implemented.

### SUMMARY

Embodiments of the present disclosure provide a display device having improved durability by preventing penetration of moisture and oxygen and occurrence of defects due to an external pressure and an electronic device including the same.

Embodiments of the present disclosure also provide a method of manufacturing a display device having improved reliability.

According to an embodiment, a display device includes a display panel including a first area and a bending area adjacent to the first area, the bending area having a predetermined radius of curvature, a functional layer disposed on the display panel and overlapping the first area, and a bending protecting layer which is disposed on the display panel and wherein at least a portion of the bending protecting layer overlaps the bending area on a plane, wherein the functional layer includes a main part overlapping the first area and a hydrophilic coating part disposed between the main part and the bending protecting layer, and the at least a portion of the bending protecting layer is spaced a predetermined distance from the hydrophilic coating part.

The functional layer may be a reflection preventing layer.

The main part may include at least one sub-adhesive layer disposed on the display panel and at least one sub-functional layer disposed on the at least one adhesive layer.

The sub-functional layer may include an uppermost sub-functional layer disposed on an uppermost side of the main part, and the hydrophilic coating part may be disposed on at least a side surface of the uppermost sub-functional layer.

A thickness of the hydrophilic coating part may be substantially the same as a thickness of the main part.

A thickness of the hydrophilic coating part may be smaller than a thickness of the main part.

The display panel may include a base layer, a circuit layer disposed on the base layer, and a light emitting element layer disposed on the circuit layer, and the functional layer may be disposed on the light emitting element layer.

An upper surface of the hydrophilic coating part and an upper surface of the main part may be aligned with each other.

The functional layer may be an impact absorbing layer.

The display device may further include a window disposed on the functional layer.

A thickness of the functional layer may be greater than or equal to a thickness of the bending protecting layer.

The hydrophilic coating part may include a material having higher surface energy than a surface energy of the bending protecting layer.

According to an embodiment, an electronic device includes a display panel including a first area, a second area, and a bending area disposed between the first area and the second area, the bending area having a predetermined radius of curvature, a functional layer which is disposed on the display panel and of which at least a portion overlaps the first area on a plane, and a bending protecting layer disposed on the display panel and wherein at least a portion of the bending protection layer overlaps the bending area on a plane, wherein the functional layer includes a main part overlapping the first area and including at least one adhesive layer and at least one sub-functional layer, and a hydrophilic coating part disposed between the main part and the bending protecting layer.

The electronic device may further include a printed circuit board electrically connected to the second area of the display panel.

An upper surface of the hydrophilic coating part and an upper surface of the main part may be aligned with each other.

The display panel may further include pixels overlapping the first area on a plane and a driving part overlapping the second area and connected to the pixels on a plane.

According to an embodiment, a method of manufacturing a display device includes providing a display panel including a first area and a bending area adjacent to the first area, providing a preliminary functional layer on the display panel such that the preliminary functional layer overlaps the first area on a plane, forming a hydrophilic coating part by providing a hydrophilic material onto one side of the preliminary functional layer adjacent to the bending area, and forming a bending protecting layer by providing a bending protecting resin to the bending area and curing the bending protecting resin in the bending area, wherein at least a portion of the bending protecting layer is spaced a predetermined distance from the hydrophilic coating part.

Providing the preliminary functional layer may include providing a protective film on the preliminary functional layer, and the method may further include removing the protective film after forming the bending protecting layer.

Forming the hydrophilic coating part may include forming a functional layer having a main part overlapping the first area and the hydrophilic coating part and forming the main part may include forming at least one sub-adhesive layer disposed on the display panel and at least one sub-function layer disposed on the at least one adhesive layer.

After forming the hydrophilic coating part, an upper surface of the hydrophilic coating part and an upper surface of the main part may be aligned with each other.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is a perspective view illustrating a state in which the electronic device of FIG. 1 is folded.

FIG. 3 is a perspective view illustrating a state in which the electronic device of FIG. 1 is folded.

FIG. 4 is an exploded perspective view of the electronic device according to an embodiment.

FIGS. 5A and 5B are cross-sectional views of a display module according to an embodiment.

FIG. 6 is a plan view of a display panel according to an embodiment.

FIG. 7 is a cross-sectional view of a display device according to an embodiment.

FIG. 8 is a cross-sectional view illustrating a state in which a portion of the display device of FIG. 7 is bent.

FIG. 9 is an enlarged cross-sectional view of a partial area of FIG. 8.

FIG. 10A is an enlarged cross-sectional view of a partial area of FIG. 9.

FIG. 10B is an enlarged cross-sectional view of a partial area of FIG. 9.

FIG. 10C is an enlarged cross-sectional view of a partial area of FIG. 9.

FIGS. 11A is a schematic view illustrating an operation in a method of manufacturing a display device according to an embodiment.

FIGS. 11B is a schematic view illustrating an operation in the method of manufacturing a display device according to an embodiment.

FIGS. 11C is a schematic view illustrating an operation in the method of manufacturing a display device according to an embodiment.

FIGS. 11D is a schematic view illustrating an operation in the method of manufacturing a display device according to an embodiment.

### DETAILED DESCRIPTION

Since the present disclosure is variously modified and has various forms, an embodiment thereof will be illustrated in the drawings and will be described herein in detail. However, it should be understood that the present disclosure is not limited to a specific disclosure and includes all changes, equivalents, and substitutes included in the spirit and scope of the present disclosure.

In the specification, the expression that a first component (or area, layer, part, portion, etc.) is “disposed on”, “connected with” or “coupled to” a second component means that the first component is directly disposed on/connected with/coupled to the second component or means that a third component is interposed therebetween.

In the present application, the wording "directly disposed" may mean that there is no layer, no film, no area, no plate, and the like added between a part such as a layer, a film, an area, and a plate, and other parts. For example, the wording “directly disposed” may mean that an additional member such as an adhesive member is not disposed between two layers or two members.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first,” “second,” etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under,” “below,” “on,” “above,” etc. are used to describe the correlation of components illustrated in drawings. The terms that are relative in concept are described based on a direction illustrated in drawings. In the specification, the wording "disposed on" may refer to a case in which a first member is disposed under as well as on a second member.

It will be understood that the terms “include”, "comprise", "have", etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, a display device according to an embodiment of the present disclosure will be described with reference to the accompanying drawings.

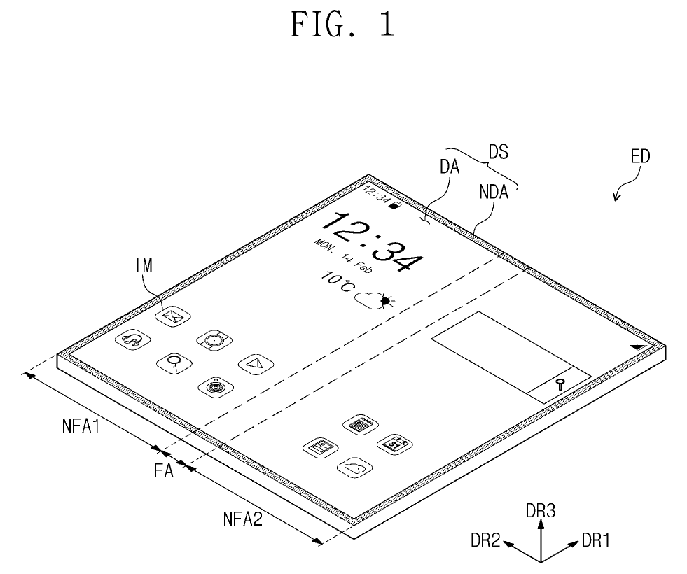

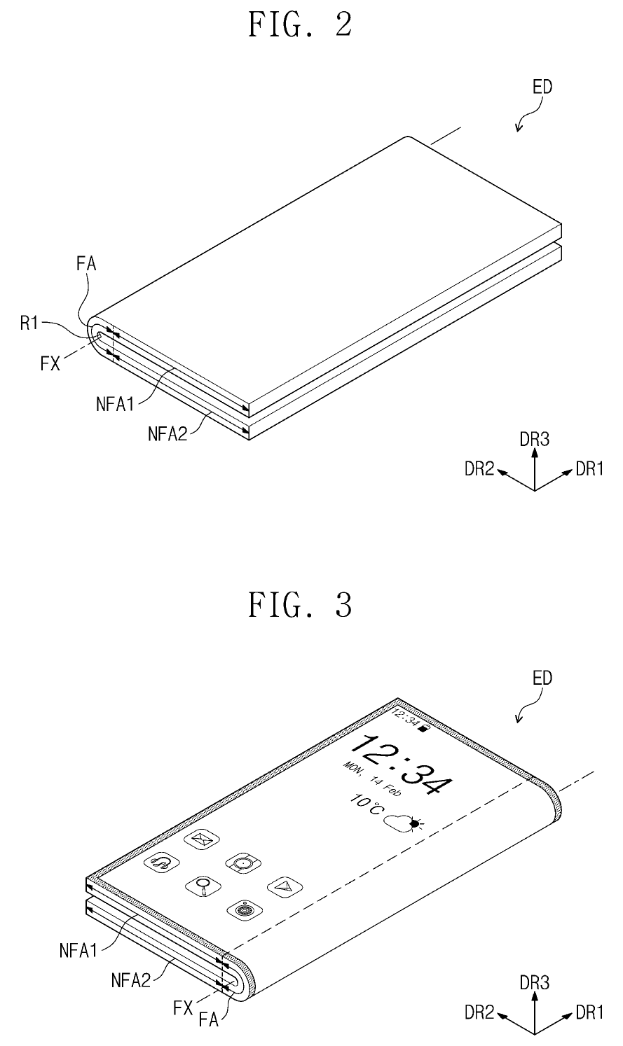

FIG. 1 is a perspective view of an electronic device according to an embodiment of the present disclosure. FIG. 2 is a perspective view illustrating a state in which the electronic device of FIG. 1 is folded. FIG. 3 is a perspective view illustrating a state in which the electronic device of FIG. 1 is folded.

An electronic device ED according to an embodiment illustrated in FIGS. 1 to 3 may be a device that is activated according to an electrical signal. For example, the electronic device ED may be a mobile phone, a tablet computer, a vehicle navigation system, a game console, or a wearable device, but an embodiment is not limited thereto. FIG. 1 illustrates, by way of example, that the electronic device ED is a smartphone.

Referring to FIG. 1, the electronic device ED according to an embodiment of the present disclosure may have a rectangular shape having two long sides extending in a first direction DR1 and two short sides extending in a second direction DR2 intersecting the first direction DR1. However, the present disclosure is not limited thereto, and the electronic device ED may have various shapes such as a circular shape and a polygonal shape.

Hereinafter, a direction substantially perpendicular to a plane defined by the first direction DR1 and the second direction DR2 is defined as a third direction DR3. Further, in the specification the wording "when viewed on a plane” may be defined as a state of being viewed from the third direction DR3.

A thickness direction of the electronic device ED may be a direction parallel to the third direction DR3, which is a normal direction to the plane defined by the first direction DR1 and the second direction DR2. In the specification, front surfaces (or upper surfaces) and rear surfaces (or lower surfaces) of members constituting the electronic device ED may be defined based on the third direction DR3. In the specification, the wording "thickness" may represent a value measured in the third direction DR3, and the wording "width" may represent a value measured in the first direction DR1 or the second direction DR2 that is horizontal direction.

The electronic device ED according to an embodiment may include a flat display surface DS. Images IM generated by the electronic device ED may be provided to a user through the display surface DS. The display surface DS may include the plane defined by the first direction DR1 and the second direction DR2. However, the present disclosure is not limited thereto, and the display surface DS may further include a curved surface bent from at least one side of the plane defined by the first direction DR1 and the second direction DR2.

The display surface DS may include a display area DA and a non-display area NDA around the display area DA. The display area DA displays an image, and the non-display area NDA does not display the image. The non-display area NDA may surround the display area DA. However, the present disclosure is not limited thereto, and the shape of the display area DA and the shape of the non-display area NDA may be modified. In an embodiment,, the non-display area NDA may be omitted.

Referring to FIGS. 1 to 3 together, the electronic device ED according to an embodiment may be a foldable electronic device.

The electronic device ED may include a folding area FA and a plurality of non-folding areas NFA1 and NFA2. For example, the non-folding areas NFA1 and NFA2 may include the first non-folding area NFA1 and the second non-folding area NFA2. The folding area FA may be disposed between the first non-folding area NFA1 and the second non-folding area NFA2. The folding area FA, the first non-folding area NFA1, and the second non-folding area NFA2 may be arranged in the second direction DR2. By way of example, one folding area FA and two non-folding areas NFA1 and NFA2 are illustrated, but the numbers of the folding areas FA and the non-folding areas NFA1 and NFA2 are not limited thereto. For example, the electronic device ED may include more than two non-folding areas, and a plurality of folding areas arranged between the non-folding areas.

As illustrated in FIG. 2, the folding area FA may be folded with respect to a folding axis FX parallel to the first direction DR1. The folding area FA has a predetermined curvature and a predetermined radius R1 of curvature. The first non-folding area NFA1 and the second non-folding area NFA2 may face each other, and the electronic device ED may be inner-folded to prevent the display surface DS from being exposed to the outside.

As illustrated in FIG. 3, the folding area FA may be outer-folded so that the display surface DS is exposed to the outside based on the folding axis FX parallel to the third direction DR1.

In an embodiment of the present disclosure, the electronic device ED may be configured to mutually repeat an inner-folding operation or an outer-folding operation from an unfolding operation, but the present disclosure is not limited thereto. In an embodiment of the present disclosure, the electronic device ED may be configured to select any one of the unfolding operation, the inner-folding operation, and the outer-folding operation.

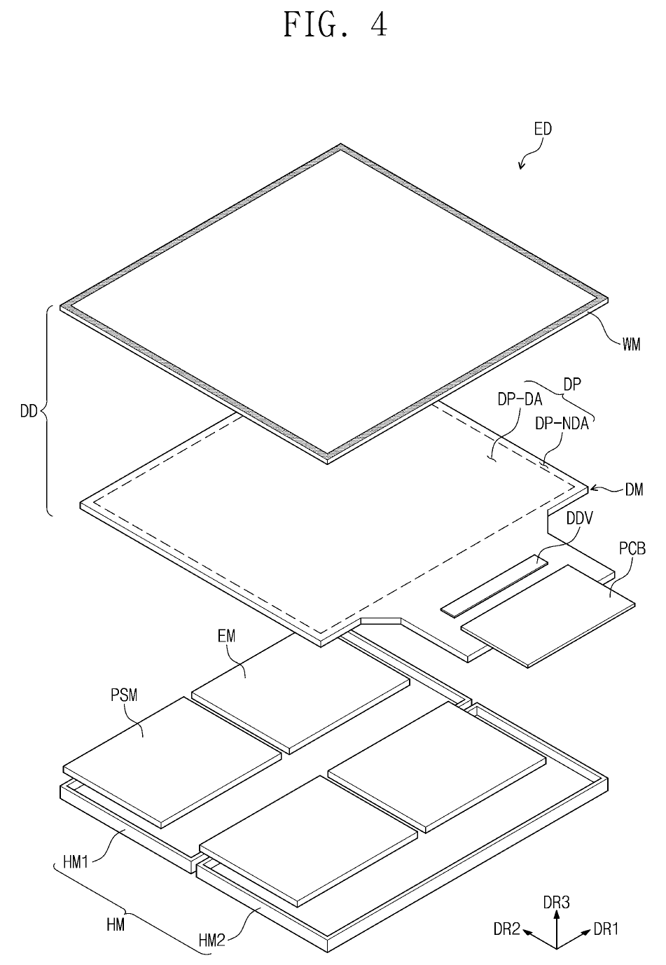

FIG. 4 is an exploded perspective view of the electronic device according to an embodiment of the present disclosure.

As illustrated in FIG. 4, the electronic device ED may include a display device DD, an electronic module EM, a power supply module PSM, and a housing HM. Although not separately illustrated, the electronic device ED may further include a mechanical structure for controlling the folding operation of the display device DD. The electronic device ED may further include an electro-optical module that outputs or receives an optical signal. The electro-optical module may include a camera module and/or a proximity sensor.

The display device DD generates an image and detects an external input. The display device DD includes a window module WM and a display module DM. The window module WM provides a front surface of the electronic device ED.

The display module DM may include at least a display panel DP. FIG. 4 illustrates only the display panel DP in a laminated structure of the display module DM, but substantially, the display module DM may further include a plurality of components arranged above the display panel DP. The laminated structure of the display module DM will be described below.

The display panel DP is not particularly limited thereto, and may be, for example, a light emitting display panel such as an organic light emitting display panel and a quantum dot light emitting display panel. The display panel DP may be a display panel including an ultra-small light emitting element such as a micro light emitting diode (LED) or a nano LED.

The display panel DP includes a display area DP-DA and a non-display area DP-NDA corresponding to the display area DA (see FIG. 1) and the non-display area NDA respectively (see FIG. 1) of the electronic device ED. In the specification, an expression "an area/part and an area/part correspond to each other" means that the area/part and the area/part overlap each other and is not limited to the same area.

As illustrated in FIG. 4, a driving part DDV may be disposed in the non-display area DP-NDA of the display panel DP. A printed circuit board PCB may be coupled to the non-display area DP-NDA of the display panel DP. Although not illustrated, the printed circuit board PCB may be connected to the display panel DP with a flexible circuit board interposed therebetween.

The driving part DDV may include driving elements, e.g., a data driver, for driving pixels of the display panel DP. FIG. 4 illustrates a structure in which the driving part DDV is mounted on the display panel DP, but the present disclosure is not limited thereto. For example, the driving part DDV may be mounted on the printed circuit board PCB.

The electronic module EM may include a control module, a wireless communication module, an image input module, a sound input module, a sound output module, a memory, an external interface module, and the like. The modules may be mounted on the printed circuit board PCB or may be electrically connected to the printed circuit board PCB through the flexible circuit board. The electronic module EM may be electrically connected to the power supply module PSM.

Referring to FIG. 4, the electronic module EM may be disposed in each of a first housing HM1 and a second housing HM2, and the power supply module PSM may be disposed in each of the first housing HM1 and the second housing HM2. Although not illustrated, the electronic module EM disposed in the first housing HM1 and the electronic module EM disposed in the second housing HM2 may be electrically connected to each other through the flexible circuit board.

The power supply module PSM supplies power for the overall operation of the electronic device ED. The power supply module PSM may include a general battery device.

The housing HM illustrated in FIG. 4 is coupled to the display device DD, particularly, the window module WM, and accommodates the other modules. It is illustrated that the housing HM includes the first housing HM1 and the second housing HM2 separated from each other, but the present disclosure is not limited thereto. Although not illustrated, the electronic device ED may further include a hinge structure for connecting the first housing HM1 and the second housing HM2.

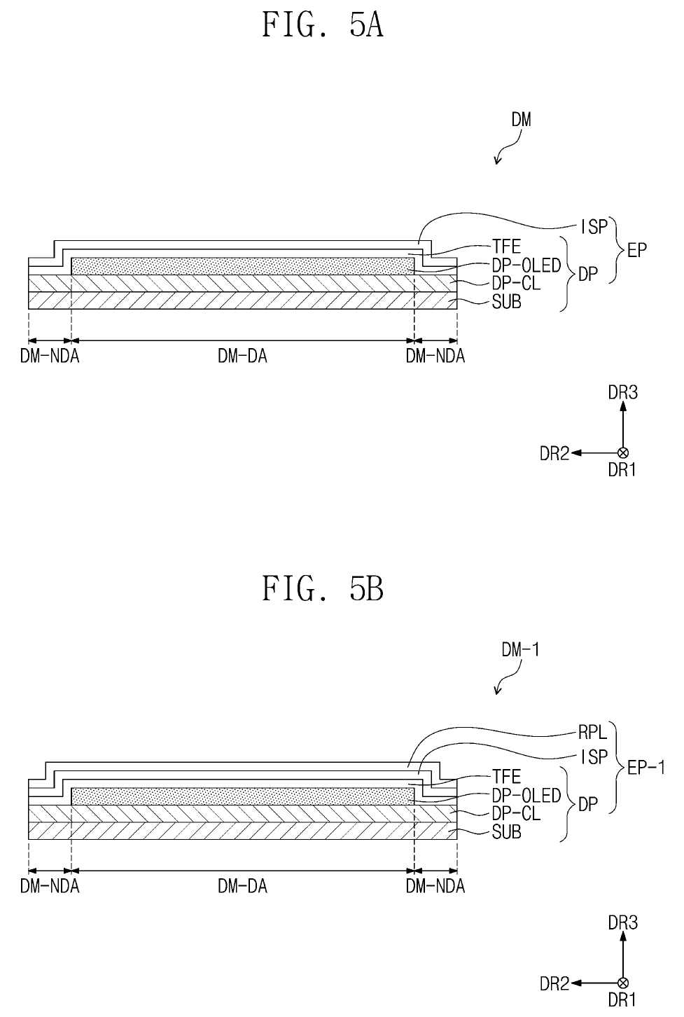

FIGS. 5A and 5B are cross-sectional views of a display module according to an embodiment.

Referring to FIG. 5A, the display module DM according to an embodiment may include an electronic panel EP. The electronic panel EP may include the display panel DP and an input sensor ISP disposed on the display panel DP. The display panel DP may include a base layer SUB, a circuit layer DP-CL disposed on the base layer SUB, a light emitting element layer DP-OLED disposed on the circuit layer DP-CL, and a thin film encapsulation layer TFE disposed on the light emitting element layer DP-OLED.

The display panel DP according to an embodiment of the present disclosure may be a light emitting display panel, but the present disclosure is not particularly limited thereto. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Further, a light emitting layer of the display panel DP may include a micro LED element and/or a nano LED element. Hereinafter, the display panel DP will be described as the organic light emitting display panel.

In the display panel DP, the base layer SUB may be a member that provides a base surface on which the light emitting element layer DP-OLED is disposed. The base layer SUB may be a glass substrate, a metal substrate, a polymer substrate, or the like. However, an embodiment is not limited thereto, and the base layer SUB may be an inorganic layer, an organic layer, or a composite material layer.

The base layer SUB may have a multi-layer structure. For example, the base layer SUB may have a three-layer structure of a polymer resin layer, an adhesive layer, and a polymer resin layer. In particular, the polymer resin layer may include a polyimide-based resin. Further, the polymer resin layer may include at least one of an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, and a perylene-based resin. In the specification, “a-based” resin means one that includes a functional group of “a.”

The circuit layer DP-CL may include an organic layer, an inorganic layer, a semiconductor pattern, a conductive pattern, a signal line, and the like. The organic layer, the inorganic layer, a semiconductor layer, and a conductive layer may be formed on the base layer SUB by methods such as coating and deposition. Thereafter, the organic layer, the inorganic layer, the semiconductor layer, and the conductive layer may be selectively patterned through a plurality of times of photolithography processes to form the semiconductor pattern, the conductive pattern, and the signal line.

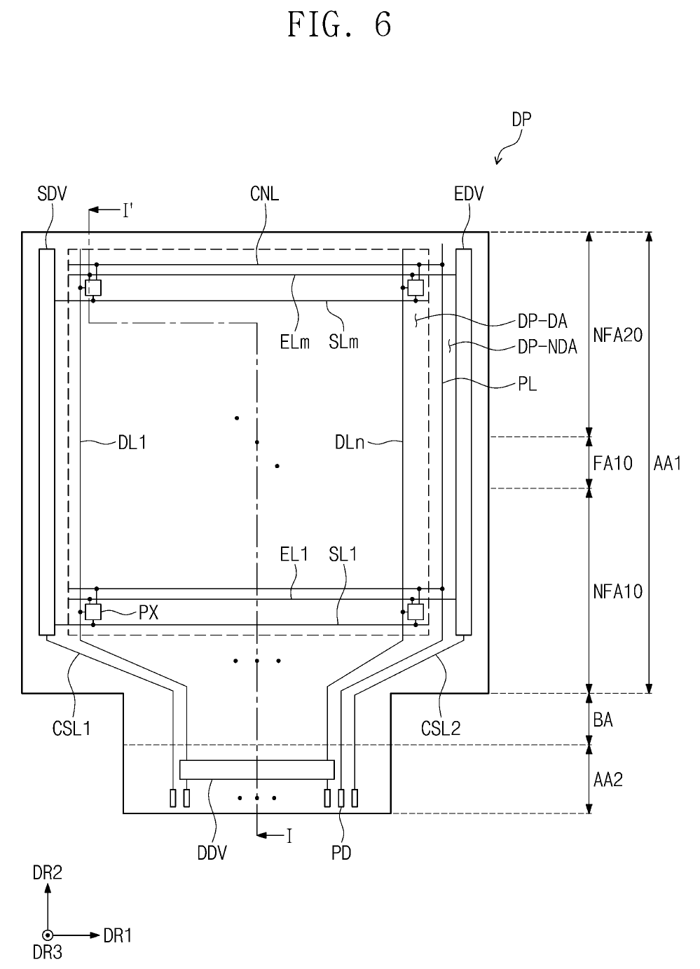

The semiconductor pattern, the conductive pattern, and the signal line may form a pixel driving circuit and signal lines SL1 to SLm, DL1 to DLn, EL1 to ELm, CSL1, CSL2, and PL (see FIG. 6) of pixels PX (see FIG. 6) to be described below. The pixel driving circuit may include at least one transistor.

The light emitting element layer DP-OLED includes light emitting elements of the pixels PX (see FIG. 6). The light emitting elements are electrically connected to the at least one transistor. In addition, the light emitting element layer DP-OLED may further include at least one of an organic layer and an inorganic layer.

The thin film encapsulation layer TFE may be disposed on the circuit layer DP-CL to cover the light emitting element layer DP-OLED. The thin film encapsulation layer TFE may protect the light emitting elements from foreign substances such as moisture/oxygen and dust particles. The thin film encapsulation layer TFE may include an inorganic layer, an organic layer, and an inorganic layer that are sequentially laminated. The laminated structure of the thin film encapsulation layer TFE is not particularly limited.

A display area DM-DA and a non-display area DM-NDA may be defined in the display module DM. The display area DM-DA and the non-display area DM-NDA of the display module DM correspond to the display area DA and the non-display area NDA of the display device DD (see FIG. 1), respectively.

The pixel driving circuit of the circuit layer DP-CL is disposed in the display area DM-DA. In addition, some of the signal lines SL1 to SLm, DL1 to DLn, EL1 to ELm, CSL1, CSL2, and PL (see FIG. 6) of the circuit layer DP-CL are arranged in the display area DM-DA and the non-display area DM-NDA.

The light emitting elements of the light emitting element layer DP-OLED are arranged in the display area DM-DA. The thin film encapsulation layer TFE is disposed in the display area DM-DA and the non-display area DM-NDA. However, the thin film encapsulation layer TFE may be sufficient to cover the display area DM-DA, and the non-display area DM-NDA may not be completely covered.

The input sensor ISP may include a plurality of electrodes (not illustrated) for detecting an external input, trace lines (not illustrated) connected to the plurality of electrodes, and an organic layer and/or an inorganic layer for insulating/protecting the plurality of electrodes or the trace lines. The input sensor ISP may be a capacitive sensor, but the present disclosure is not particularly limited thereto.

When the display module DM is manufactured, the input sensor ISP may be directly disposed on the thin film encapsulation layer TFE through a continuous process. That is, a separate adhesive member may not be disposed between the thin film encapsulation layer TFE and the input sensor ISP. However, the present disclosure is not limited thereto, and the input sensor ISP may be manufactured as a separate panel from the display module DM and may be attached to the display module DM by an adhesive layer.

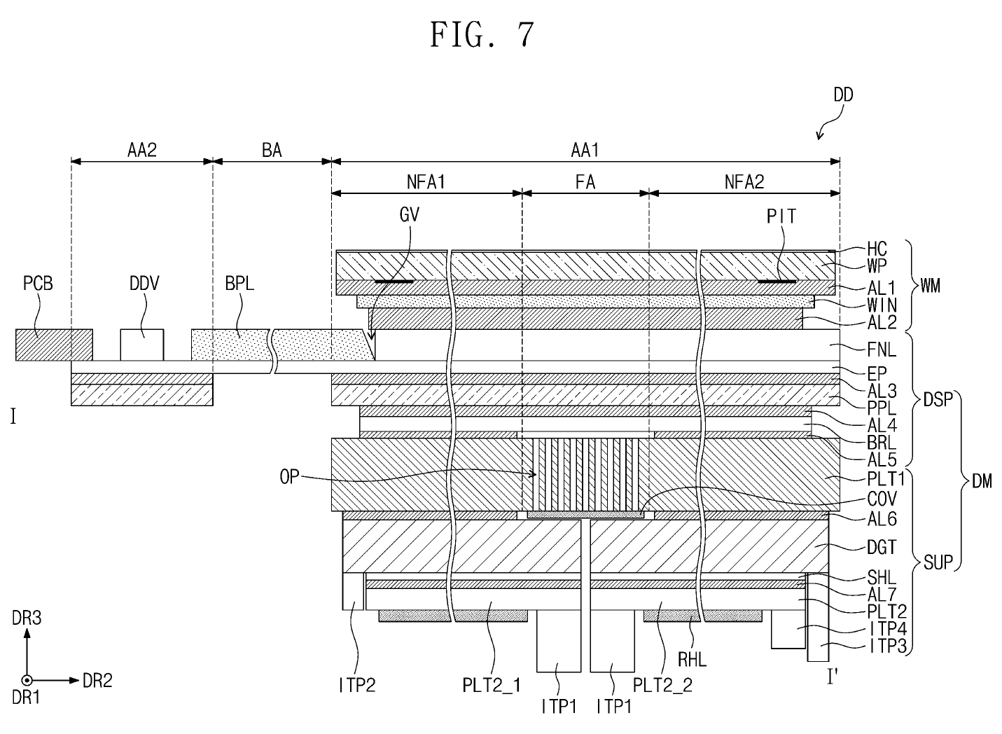

Although not illustrated in FIG. 5A, the display module DM may further include a functional layer FNL (see FIG. 7) disposed on the electronic panel EP. The functional layer FNL may be a reflection preventing layer or an impact absorbing layer. The functional layer FNL may be manufactured separately from the electronic panel EP, may be disposed on the electronic panel EP, may include an adhesive layer, and may be coupled to the electronic panel EP. A description related to the functional layer FNL will be made below in detail with reference to FIG. 7.

A display module DM-1 of FIG. 5B includes an electronic panel EP-1 of the present disclosure having a structure different from that of the electronic panel EP illustrated in FIG. 5A. Referring to FIG. 5B, the electronic panel EP-1 according to an embodiment may include a reflection preventing layer RPL. The reflection preventing layer RPL may be directly formed on the input sensor ISP when the display module DM-1 is manufactured.

The reflection preventing layer RPL may reduce reflectance of external light incident on the display device DD (see FIG. 1). The reflection preventing layer RPL may include an optical film for reducing the reflectance of the external light. For example, the reflection preventing layer RPL may include a plurality of color filters and a light shielding pattern or may include a reflection adjusting layer including pigments and/or dyes.

FIG. 6 is a plan view of a display panel according to an embodiment.

Referring to FIG. 6, the display panel DP may include the display area DP-DA and the non-display area DP-NDA around the display area DP-DA. The display area DP-DA and the non-display area DP-NDA are distinguished from each other according to whether the pixels PX are arranged. The display area DP-DA and the non-display area DP-NDA correspond to the display area DA and the non-display area NDA of the display device DD (see FIG. 1), respectively. A scan driver SDV, a data driver DDV, and an emission driver EDV may be arranged in the non-display area DP-NDA.

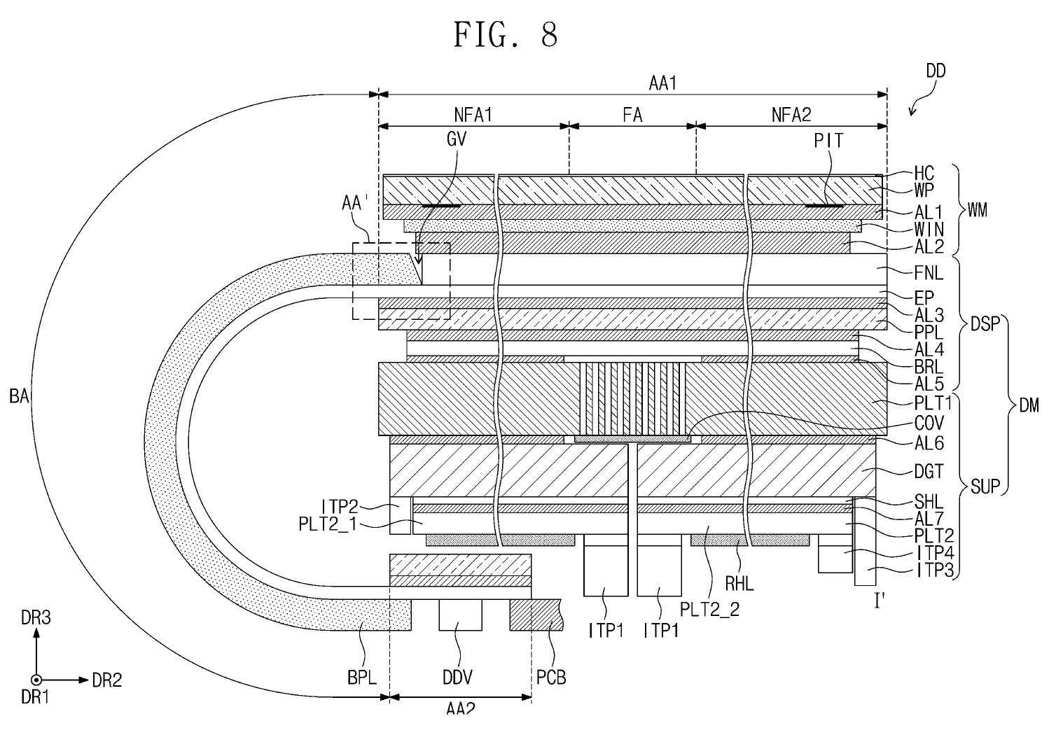

The display panel DP includes a first area AA1, a second area AA2, and a bending area BA, which are separated from each other in the second direction DR2. In a state in which the display device DD is unfolded as illustrated in FIG. 1, the first area AA1 and the second area AA2 of the display panel DP mounted on the display device DD are arranged on different planes. The bending area BA is disposed between the first area AA1 and the second area AA2. A bending shape of the bending area BA will be described below with reference to FIG. 8. FIG. 6 illustrates an unfolded state before the display panel DP is mounted on the display device DD.

The first area AA1 is an area corresponding to the display surface DS (see FIG. 1). The first area AA1 may include a first non-folding area NFA10, a second non-folding area NFA20, and a folding area FA0. The first non-folding area NFA10, the second non-folding area NFA20, and the folding area FA0 correspond to the first non-folding area NFA1, the second non-folding area NFA2, and the folding area FA of FIGS. 1 to 3, respectively.

The lengths of the bending area BA and the second area AA2 in the second direction DR2 may be smaller than the length of the first area AA1. The second area AA2 and the bending area BA may be partial areas of the non-display area DP-NDA.

The display panel DP may include the plurality of pixels PX, the plurality of scan lines SL1 to SLm, the plurality of data lines DL1 to DLn, the plurality of light emitting lines EL1 to ELm, the first control line CSL1, the second control line CSL2, the power line PL, and a plurality of pads PD. In this case, “m” and “n” are natural numbers. The pixels PX may be connected to the scan lines SL1 to SLm, the data lines DL1 to DLn, and the light emitting lines EL1 to ELm.

The data driver DDV may be disposed in the second area AA2. The data driver DDV may be an integrated circuit chip. The scan lines SL1 to SLm may extend in the second direction DR2 and may be connected to the scan driver SDV. The data lines DL1 to DLn may extend in the first direction DR1 and may be connected to the data driver DDV via the bending area BA. The light emitting lines EL1 to ELm may extend in the second direction DR2 and may be connected to the emission driver EDV.

The power line PL may extend in the second direction DR2 and may extend from the first area AA1 via the bending area BA to the second area AA2. The power line PL may provide driving voltages to the pixels PX. The power line PL may be disposed in the non-display area DP-NDA. The power line PL may extend in the second direction DR2 and may be disposed in the non-display area NDA. It is illustrated that the power line PL is disposed between the display area DA and the emission driver EDV, but the present disclosure is not limited thereto, and the power line PL may also be disposed between the display area DA and the scan driver SDV.

Connection lines CNL may extend in the first direction DR1 and may be arranged in the second direction DR2. The connection lines CNL may be connected to the power line PL and the pixels PX. The driving voltage may be applied to the pixels PX through the power line PL and the connection lines CNL connected to each other.

The first control line CSL1 may be connected to the scan driver SDV and may extend toward a lower end of the second area AA2 via the bending area BA. The second control line, CSL2, may be connected to the emission driver EDV and may extend toward the lower end of the second area AA2 via the bending area BA.

When viewed on a plane, the pads PD may be arranged adjacent to the lower end of the second area AA2. The data driver DDV, the power line PL, the first control line CSL1, and the second control line CSL2 may be connected to the pads PD. The data lines DL1 to DLn may be connected to corresponding pads PD through the data driver DDV. For example, the data lines DL1 to DLn may be connected to the data driver DDV, and the data driver DDV may be connected to the pads PD respectively corresponding to the data lines DL1 to DLn.

Although not illustrated, a printed circuit board may be connected to the pads PD, and a timing controller and a voltage generator may be arranged on the printed circuit board. The timing controller may be manufactured as an integrated circuit chip and mounted on the printed circuit board. The timing controller and the voltage generator may be connected to the pads PD through the printed circuit board. The timing controller may control operations of the scan driver SDV, the data driver DDV, and the emission driver EDV. The timing controller may generate a scan control signal, a data control signal, and a light emitting control signal in response to control signals received from an external unit. The scan control signal may be provided to the scan driver SDV through the first control line CSL1. The light emitting control signal may be provided to the emission driver EDV through the second control line CSL2. The data control signal may be provided to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to image signals in response to the data control signal. The data voltages may be applied to the pixels PX through the data lines DL1 to DLn.

The emission driver EDV may generate a plurality of light emitting signals in response to the light emitting control signal. The light emitting signals may be applied to the pixels PX through the light emitting lines EL1 to ELm.

The pixels PX may receive the data voltages in response to the scan signals. The pixels PX may display an image by emitting lights having luminances corresponding to the data voltages in response to the light emitting signals. Light emitting times of the pixels PX may be controlled by the light emitting signals.

FIG. 7 is a cross-sectional view of a display device according to an embodiment. FIG. 8 is a cross-sectional view illustrating a state in which a portion of the display device of FIG. 7 is bent.

FIG. 7 is a cross-sectional view along line I-I’ illustrated in FIG. 6. FIG. 7 illustrates both a cross section of the display module DM and a cross section of the window module WM corresponding to line I-I’.

Referring to FIG. 7, the display device DD may include the display module DM and the window module WM disposed on the display module DM. The window module WM may be disposed on the display module DM to protect the display module DM.

The display module DM may include a display part DSP and a support part SUP. The support part SUP may be disposed under the display part DSP to support the display part DSP.

The window module WM may include a window WIN, a window protecting layer WP, a hard coating layer HC, a first adhesive layer AL1, and a second adhesive layer AL2. The display part DSP may include the electronic panel EP, the functional layer FNL, a panel protecting layer PPL, a barrier layer BRL, a third adhesive layer AL3, a fourth adhesive layer AL4, and a fifth adhesive layer AL5.

The electronic panel EP may be the electronic panel EP illustrated in FIG. 5A, or the electronic panel EP-1 illustrated in FIG. 5B. Like the display panel DP, the electronic panel EP may include the first area AA1, the second area AA2, and the bending area BA between the first area AA1 and the second area AA2. The functional layer FNL may be disposed on the electronic panel EP.

As described above, the functional layer FNL may be a reflection preventing layer or an impact absorbing layer. When the functional layer FNL is the reflection preventing layer, the functional layer FNL may reduce reflectance of external light incident on the display device DD. The functional layer FNL may include an optical film for reducing reflectance of external light. For example, the functional layer FNL may include a phase retarder and/or a polarizer. For example, the functional layer FNL may include a polarizing film.

When the functional layer FNL is the impact absorbing layer, the functional layer FNL may protect the electronic panel EP by absorbing an external impact applied from an upper side of the display device DD toward the electronic panel EP. The functional layer FNL may be manufactured in the form of a stretched film. When the functional layer FNL is the impact absorbing layer, the electronic panel EP may include a separate reflection preventing layer, and for example, as described in FIG. 5B, include the plurality of color filters and the light shielding pattern or the reflection preventing layer RPL (see FIG. 5B) including a reflection adjusting layer including a pigment and/or a dye.

The functional layer FNL may include a base layer including a flexible resin material. The base layer including the flexible resin material may be defined as a synthetic resin film. For example, the functional layer FNL may include a base layer including a flexible resin material such as polyimide (PI) or polyethylene terephthalate (PET).

The window WIN may be disposed on the functional layer FNL. The window WIN may protect the electronic panel EP from external scratches. The window WIN may have optically transparent properties. The window WIN may include glass. However, the present disclosure is not limited thereto, and the window WIN may include a synthetic resin film.

The window WIN may have a multi-layer structure or a single-layer structure. For example, the window WIN may include a plurality of synthetic resin films coupled with an adhesive or may include a glass substrate and a synthetic resin film coupled with an adhesive.

The window protecting layer WP may be disposed on the window WIN. The window protecting layer WP may include a flexible resin material such as polyimide or polyethylene terephthalate. The hard coating layer HC may be disposed on an upper surface of the window protecting layer WP.

A printing layer PIT may be disposed on a lower surface of the window protecting layer WP. The printing layer PIT may have black color, but the color of the printing layer PIT is not limited thereto. On a plane, the printing layer PIT may be disposed adjacent to an edge of the window protecting layer WP.

The panel protecting layer PPL may be disposed under the electronic panel EP including the display panel DP (see FIG. 5A). The panel protecting layer PPL may protect a lower portion of the electronic panel EP. The panel protecting layer PPL may include a flexible resin material. For example, the panel protecting layer PPL may include polyethylene terephthalate (PET).

The barrier layer BRL may be disposed under the panel protecting layer PPL. The barrier layer BRL may increase resistance against a compressive force caused by external pressure. The barrier layer BRL may serve to prevent deformation of the electronic panel EP. The barrier layer BRL may include a flexible resin material such as polyimide or polyethylene terephthalate.

The barrier layer BRL may be colored such that it absorbs wavelengths of light. For example, the barrier layer BRL may be colored black. In this case, when the display module DM is viewed from an upper side of the display module DM, components arranged under the barrier layer BRL may not be visually recognizable.

The first adhesive layer AL1 may be disposed between the window protecting layer WP and the window WIN. The window protecting layer WP and the window WIN may be bonded to each other by the first adhesive layer AL1. In an embodiment, the printing layer PIT may be disposed between the window protecting layer WP and the first adhesive layer AL1.

The second adhesive layer AL2 may be disposed between the window WIN and the functional layer FNL. The window WIN and the functional layer FNL may be bonded to each other by the second adhesive layer AL2.

The third adhesive layer AL3 may be disposed between the electronic panel EP and the panel protecting layer PPL. The electronic panel EP and the panel protecting layer PPL may be bonded to each other by the third adhesive layer AL3.

The fourth adhesive layer AL4 may be disposed between the panel protecting layer PPL and the barrier layer BRL. The panel protecting layer PPL and the barrier layer BRL may be bonded to each other by a fourth adhesive layer AL4.

The fifth adhesive layer AL5 may be disposed between the barrier layer BRL and a first support plate PLT1. The barrier layer BRL and the first support plate PLT1 may be bonded to each other by the fifth adhesive layer AL5.

The fifth adhesive layer AL5 may overlap the first non-folding area NFA1 and the second non-folding area NFA2 and may not overlap the folding area FA. That is, the fifth adhesive layer AL5 may include an opening corresponding to the folding area FA.

The first to fifth adhesive layers AL1 to AL5 may include a transparent adhesive such as a pressure sensitive adhesive (PSA) or an optically clear adhesive (OCA), but the type of adhesive is not limited thereto.

Widths of the window WIN and the second adhesive layer AL2 may be smaller than widths of the window protecting layer WP and the first adhesive layer AL1. The width of the second adhesive layer AL2 may be smaller than the width of the window WIN. An edge of the window WIN may be disposed inside edges of the window protecting layer WP and the first adhesive layer AL1. An edge of the second adhesive layer AL2 may be disposed inside the edge of the window WIN.

Widths of the barrier layer BRL, the fourth adhesive layer AL4, and the fifth adhesive layer AL5 may be smaller than widths of the window protecting layer WP and the first adhesive layer AL1. Edges of the barrier layer BRL, the fourth adhesive layer AL4, and the fifth adhesive layer AL5 may be arranged inside the edges of the window protecting layer WP and the first adhesive layer AL1. However, the width of each component is not limited thereto.

The support part SUP may include the first support plate PLT1, a second support plate PLT2, a cover layer COV, a digitizer DGT, a shielding layer SHL, a heat dissipating layer RHL, a sixth adhesive layer AL6, a seventh adhesive layer AL7, a first insulating tape ITP1, a second insulating tape ITP2, a third insulating tape ITP3, and a fourth insulating tape ITP4.

The first support plate PLT1 may be disposed under the electronic panel EP to support the electronic panel EP. The first support plate PLT1 may be disposed under the barrier layer BRL.

Rigidity of the first support plate PLT1 may be greater than rigidity of the display part DSP. The first support plate PLT1 may include a non-metallic material. For example, the first support plate PLT1 may include a reinforcing fiber composite. The reinforced fiber composite may be carbon fiber reinforced plastic (CFRP) or glass fiber reinforced plastic (GFRP).

The first support plate PLT1 may include a reinforced fiber composite and thus may be lightened. The first support plate PLT1 according to an embodiment may include the reinforced fiber composite, thus have a light weight compared to a metal support plate using a metal material and have a modulus and a strength similar to those of the metal support plate.

The first support plate PLT1 may include a reinforced fiber composite, and thus a shape of the first support plate PLT1 may be easily processed as compared with the metal support plate. For example, the first support plate PLT1 including the reinforced fiber composite material may be more easily processed through a laser process or a microblast process.

A plurality of openings OP may be defined in a portion of the first support plate PLT1 overlapping the folding area FA. The openings OP may be formed by passing through portions of the first support plate PLT1 in the third direction DR3. The openings OP may be formed through the above-described laser process or the above-described microblast process.

As the openings OP are defined in the portion of the first support plate PLT1 overlapping the folding area FA, flexibility of the portion of the first support plate PLT1 overlapping the folding area FA may be increased. As a result, the first support plate PLT1 may be easily folded about the folding area FA.

The cover layer COV may be disposed under the first support plate PLT1. The cover layer COV may cover the openings OP defined in the first support plate PLT1 under the first support plate PLT1. The cover layer COV may overlap the folding area FA and may not overlap the first non-folding area NFA1 and the second non-folding area NFA2. That is, the cover layer COV may not be disposed in the first non-folding area NFA1 and the second non-folding area NFA2. The cover layer COV may be in contact with a lower surface of the portion of the first support plate PLT1 in which the openings OP are formed.

The cover layer COV may have a lower elastic modulus than that of the first support plate PLT1. For example, the cover layer COV may include thermoplastic polyurethane or rubber, but the material of the cover layer COV is not limited thereto. The cover layer COV may be manufactured in a seat shape and attached to the first support plate PLT1.

The digitizer DGT may be disposed under the first support plate PLT1. The cover layer COV may be disposed between the first support plate PLT1 and the digitizer DGT. The cover layer COV may be spaced apart from an upper surface of the digitizer DGT.

The digitizer DGT is a device that may receive position information indicated by the user on a display surface. The digitizer DGT may be implemented in an electromagnetic manner (or an electromagnetic resonance manner). For example, the digitizer DGT may include a digitizer sensor substrate (not illustrated) including a plurality of coils. However, the present disclosure is not limited thereto, and the digitizer DGT may be implemented in an active electrostatic manner.

When the user moves a pen on the display device DD, the pen may be driven by an (alternating current) AC signal to cause a vibrating magnetic field, and the vibrating magnetic field may induce a signal to the coil. A position of the pen may be detected through the signal induced to the coil. The digitizer DGT may detect an electromagnetic change caused by approach of the pen and identify the position of the pen.

When the first support plate PLT1 disposed on the digitizer DGT and adjacent to the digitizer DGT includes a metal, sensitivity of the digitizer DGT may be lowered by the metal. For example, the digitizer DGT may not normally operate when the signal transmitted on the display device DD is blocked due to signal interference by the metal support plate. However, in an embodiment of the present disclosure, since the first support plate PLT1 disposed on the digitizer DGT includes a non-metal reinforced fiber composite, the digitizer DGT may operate normally.

The digitizer DGT may be divided into two parts in the folding area FA. The parts of the digitizer DGT, which are separated from each other, may be connected to a digitizer driver (not illustrated) through the flexible circuit boards.

The shielding layer SHL may be disposed under the digitizer DGT. The shielding layer SHL may include a metal. For example, the shielding layer SHL may include copper, but the metal material of the shielding layer SHL is not limited thereto. The shielding layer SHL may be divided into two parts in the folding area FA. The parts of the shielding layer SHL, which are separated from each other, may be arranged under the parts of the digitizer DGT, which are separated from each other.

The shielding layer SHL may shield an electromagnetic wave that may be applied to the digitizer DGT below the display device DD. The shielding layer SHL may be defined as an electromagnetic shielding layer. The shielding layer SHL including a metal may serve as a heat dissipating layer.

The second support plate PLT2 may be disposed under the shielding layer SHL. The second support plate PLT2 may have higher rigidity than that of the display part DSP. The second support plate PLT2 may include a metal material (e.g., SUS 316) such as stainless steel, but the metal material of the second support plate PLT2 is not limited thereto. Further, the present disclosure is not limited thereto, and the second support plate PLT2 may include a non-metallic material such as plastic.

The second support plate PLT2 may be divided into two parts in the folding area FA. For example, the second support plate PLT2 may include a (2-1)^{th} support plate PLT2_1 overlapping the first non-folding area NFA1 and a (2-2)^{th} support plate PLT2_2 overlapping the second non-folding area NFA2.

The (2-1)^{th} support plate PLT2_1 may support the first non-folding area NFA1. The (2-2)^{th} support plate PLT2_2 may support the second non-folding area NFA2. The (2-1)^{th} support plate PLT2_1 and the (2-2)^{th} support plate PLT2_2 may extend to the folding area FA and may be arranged adjacent to each other in the folding area FA. The (2-1)^{th} support plate PLT2_1 and the (2-2)^{th} support plate PLT2_2 may be spaced apart from each other below the folding area FA.

The (2-1)^{th} support plate PLT2_1 and the (2-2)^{th} support plate PLT2_2 may support a portion of the first support plate PLT1 in which the openings OP are defined below the folding area FA. When a pressure is applied to the first support plate PLT1 from an upper side, deformation of a portion of the first support plate PLT1 in which the openings OP are defined may be prevented by the (2-1)^{th} support plate PLT2_1 and the (2-2)^{th} support plate PLT2_2. Additionally, the (2-1)^{th} support plate PLT2_1 and the (2-2)^{th} support plate PLT2_2 may perform a heat dissipating function.

The heat dissipating layer RHL may be disposed under the second support plate PLT2. The heat dissipating layer RHL may be divided into two parts in the folding area FA. The parts of the heat dissipating layer RHL, which are separated from each other, may be arranged under the (2-1)^{th} support plate PLT2_1 and the (2-2)^{th} support plate PLT2_2, respectively.

The heat dissipating layer RHL may perform a heat dissipating function. For example, the heat dissipating layer RHL may include graphite, but the material of the heat dissipating layer RHL is not limited thereto. The heat dissipating layer RHL may perform a heat dissipating function together with the second support plate PLT2 and the shielding layer SHL, and thus heat dissipating performance of the display device DD may be improved.

The first insulating tape ITP1, the second insulating tape ITP2, the third insulating tape ITP3, and the fourth insulating tape ITP4 may be arranged under the digitizer DGT and the second support plate PLT2. The first insulating tape ITP1, the second insulating tape ITP2, the third insulating tape ITP3, and the fourth insulating tape ITP4 may include an insulating material.

The two first insulating tapes ITP1 may be arranged adjacent to one side of the (2-1)^{th} support plate PLT2_1 and one side of the (2-2)^{th} support plate PLT2_2 facing each other and under the (2-1)^{th} support plate PLT2_1 and the (2-2)^{th} support plate PLT2_2.

The second insulating tape ITP2 and the third insulating tape ITP3 may be arranged adjacent to both sides of the digitizer DGT and under the digitizer DGT. The second insulating tape ITP2 may be adjacent to an edge of the (2-1)^{th} support plate PLT2_1, and the third insulating tape ITP3 may be adjacent to an edge of the (2-2)^{th} support plate PLT2_2.

The fourth insulating tape ITP4 may be adjacent to an opposite side of the (2-2)^{th} support plate PLT2_2 opposite to the one side of the (2-2)^{th} support plate PLT2_2. The fourth insulating tape ITP4 may be disposed under the (2-2)^{th} support plate PLT2_2.

The shielding layer SHL, the second support plate PLT2, the heat dissipating layer RHL, the first insulating tapes ITP1, and the fourth insulating tape ITP4 may be arranged between the second insulating tape ITP2 and the third insulating tape ITP3. One of the heat dissipating layers RHL separated from each other may be disposed between the first insulating tape ITP1 and the fourth insulating tape ITP4 arranged under the (2-2)^{th} support plate PLT2_2. The other one of the heat dissipating layers RHL separated from each other may be disposed between the first insulating tape ITP1 disposed under the (2-1)^{th} support plate PLT2_1 and the second insulating tape ITP2 disposed under the digitizer DGT.

The sixth adhesive layer AL6 may be disposed between the first support plate PLT1 and the digitizer DGT. The first support plate PLT1 and the digitizer DGT may be bonded to each other by the sixth adhesive layer AL6. The sixth adhesive layer AL6 may not be disposed in the folding area FA. That is, the sixth adhesive layer AL6 may be open in the folding area FA.

The cover layer COV may be disposed in the opening of the sixth adhesive layer AL6. The sixth adhesive layer AL6 is not disposed under the folding area FA, and thus the support part SUP may be more easily folded.

The seventh adhesive layer AL7 may be disposed between the shielding layer SHL and the second support plate PLT2. The shielding layer SHL and the second support plate PLT2 may be bonded to each other by the seventh adhesive layer AL7. The seventh adhesive layer AL7 may be separated in the folding area FA. Parts of the seventh adhesive layer AL7, which are separated from each other, may be arranged between the parts of the shielding layer SHL, which are separated from each other, and the (2-1)^{th} support plate PLT2_1 and the (2-2)^{th} support plate PLT2_2. The seventh adhesive layer AL7 may be disposed between the second insulating tape ITP2 and the third insulating tape ITP3.

A width of the first support plate PLT1 may be substantially the same as a width of the electronic panel EP. Widths of the digitizer DGT and the sixth adhesive layer AL6 may be smaller than the width of the first support plate PLT1. Edges of the digitizer DGT and the sixth adhesive layer AL6 may be arranged inside an edge of the first support plate PLT1.

Widths of the shielding layer SHL, the seventh adhesive layer AL7, and the second support plate PLT2 may be smaller than the width of the digitizer DGT.

Edges of the shielding layer SHL, the seventh adhesive layer AL7, and the second support plate PLT2 may be arranged inside the edge of the digitizer DGT.

The sixth adhesive layer AL6 and the seventh adhesive layer AL7 may include the pressure sensitive adhesive (PSA) or the optically clear adhesive (OCA), but the type of the adhesive is not limited thereto.

The display device DD includes a bending protecting layer BPL. The bending protecting layer BPL is disposed to overlap at least the bending area BA on a plane. The bending protecting layer BPL may overlap the bending area BA, the first area AA1, and the second area AA2. The bending protecting layer BPL may be disposed on a portion of the first area AA1 and a portion of the second area AA2. The printed circuit board PCB may be connected to one side of the second area AA2.

The data driver DDV and the printed circuit board PCB may be arranged at one end of the second area AA2. The bending protecting layer BPL may be spaced apart from the data driver DDV.

Referring to FIG. 8, the bending area BA may be bent such that the second area AA2 is disposed below the first area AA1. That is, the first area AA1 and the second area AA2 are arranged on different planes (or reference planes). The bending area BA is bent to be convex in a horizontal direction on a cross section. The bending area BA has a predetermined curvature and a predetermined radius of curvature. The radius of curvature may be in a range of about 0.1 mm to about 0.5 mm.

Accordingly, the panel protecting layer PPL and the third adhesive layer AL3 may be arranged on the electronic panel EP in the second area AA2 based on the third direction DR3. The data driver DDV and the printed circuit board PCB may be arranged under the electronic panel EP in the second area AA2.

The bending protecting layer BPL may be bent together with the bending area BA. The bending protecting layer BPL may protect the bending area BA from an external impact. The bending protecting layer BPL may cover and protect the signal lines CSL1, DL1 to DLn, PL, and CSL2 (see FIG. 6) arranged in the bending area BA. Further, the bending protecting layer BPL may supplement rigidity of the bending area BA and prevent cracks in the bending area BA when the bending area BA is bent.

The bending protecting layer BPL may include an epoxy-based resin, an acryl-based resin, a urethane-based resin, or a urethane acrylate-based resin. For example, the bending protecting layer BPL may include an acryl-based resin or a urethane-based resin.

One side surface of the bending protecting layer BPL disposed in the first area AA1 may face one side surface of the functional layer FNL adjacent to the bending area BA. The one side surface of the functional layer FNL is spaced a predetermined distance GV from the one side surface of the bending protecting layer BPL. The predetermined distance GV may be provided between the one side surface of the bending protecting layer BPL and the one side surface of the functional layer FNL arranged in the first area AA1.

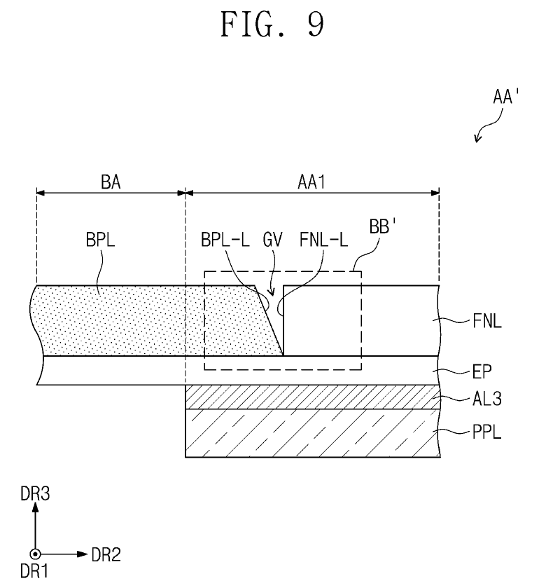

FIG. 9 is an enlarged cross-sectional view of a partial area of FIG. 8. FIG. 9 is an enlarged cross-sectional view of area AA’ of FIG. 8 according to an embodiment. Hereinafter, a description will be made based on the electronic panel EP including the display panel DP (see FIG. 4). For convenience of description, the second adhesive layer AL2 is omitted from area AA’. FIG. 9 is an enlarged cross-sectional view of portions of the bending area BA and the first area AA1.

Referring to FIG. 9, the functional layer FNL is disposed on the electronic panel EP and overlaps the first area AA1 on a plane. The functional layer FNL may be directly disposed on the electronic panel EP.

The bending protecting layer BPL is disposed on the electronic panel EP and overlaps the bending area BA, a portion of the first area AA1, and a portion of the second area AA2 (see FIGS. 7 and 8) on a plane. The bending protecting layer BPL may be directly disposed on the electronic panel EP.

The bending protecting layer BPL may face the functional layer FNL. The functional layer FNL may include a first side surface FNL-L, which is a side surface adjacent to the bending protecting layer BPL, and the bending protecting layer BPL may include a second side surface BPL-L facing the functional layer FNL. The first side surface FNL-L and the second side surface BPL-L may be spaced apart from each other.

FIG. 9 illustrates, by way of example, that the first side surface FNL-L and the second side surface BPL-L are entirely spaced apart from each other and are in contact with the base surface of the electronic panel EP, but the present disclosure is not limited thereto, and at least portions of the first side surface FNL-L and the second side surface BPL-L may be in contact with each other. The first side surface FNL-L and the second side surface BPL-L may be spaced apart from each other on the upper side and may be spaced apart from or in contact with each other on the lower side. E.g. the second side surface BPL-L may be sloped.

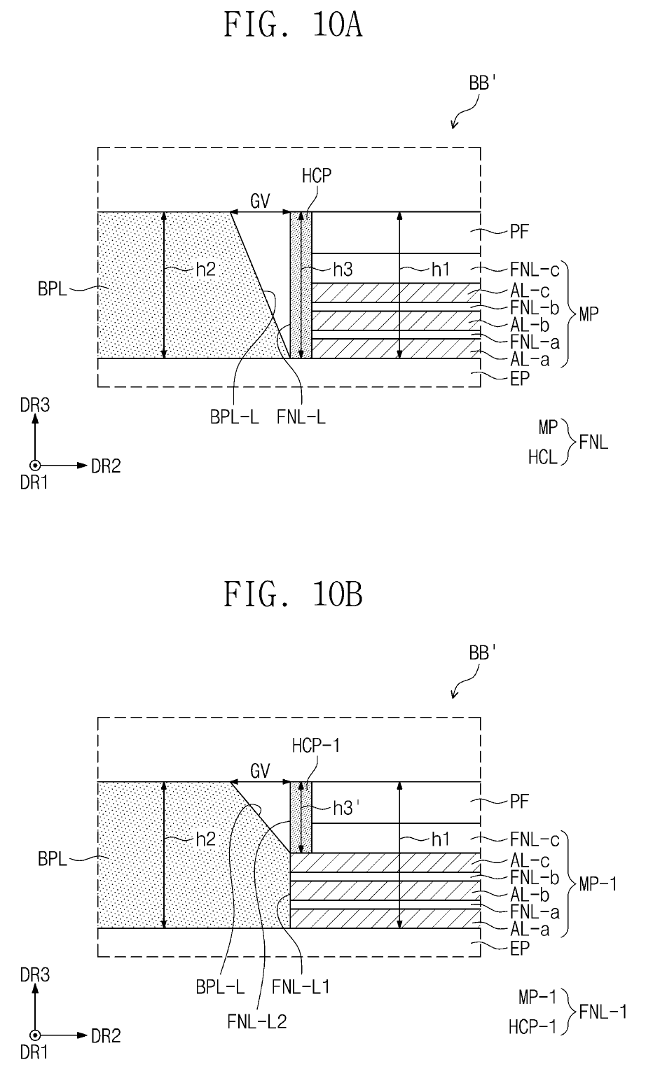

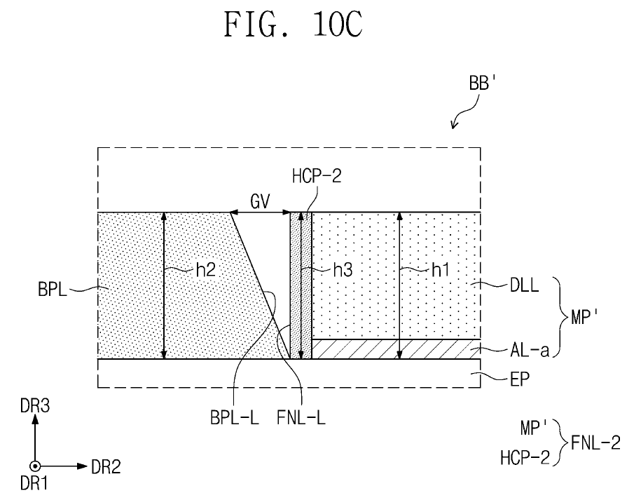

FIG. 9 illustrates a flat state before the folding area FA of the display device DD (see FIG. 7) according to an embodiment is folded, and when the display device DD is folded based on the folding axis, the first side surface FNL-L and the second side surface BPL-L may be in contact with each other. In detail, as the display device DD is inner-folded, the functional layer FNL disposed on the electronic panel EP may slip toward the bending area BA. For example, the functional layer FNL may slip from the first area AA1 toward the bending area BA by sub-adhesive layers AL-a, AL-b, and AL-c (see FIG. 10A) included in the functional layer FNL and having fluidity. As the display device DD is folded, the functional layer FNL may slip toward the bending area BA, and thus the first side surface FNL-L of the functional layer FNL may come into contact with at least a portion of the second side surface BPL-L of the bending protecting layer BPL.

FIGS. 10A to 10C are enlarged cross-sectional views of a partial area of FIG. 9. FIGS. 10A to 10C are enlarged cross-sectional views of area BB’ of FIG. 9 according to an embodiment.

Referring to FIG. 10A, the functional layer FNL includes a main part MP and a hydrophilic coating part HCP.

The main part MP may be a part that performs a main function of the functional layer FNL. When the functional layer FNL is the reflection preventing layer, the main part MP may include a phase retarder and/or a polarizer. When the functional layer FNL is the reflection preventing layer, the main part MP may include a polarizing film. When the functional layer FNL is the impact absorbing layer, the main part MP may include a flexible resin film for absorbing an impact. The main part MP may include a base layer. The main part MP may include an adhesive layer for bonding the functional layer FNL to the electronic panel EP.

In an embodiment illustrated in FIG. 10A, the main part MP may include at least one sub-adhesive layer AL-a, AL-b, or AL-c and at least one sub-functional layer FNL-a, FNL-b, FNL-c, or PF disposed on the at least one sub-adhesive layer AL-a, AL-b, or AL-c. For example, as illustrated in FIG. 10A, the functional layer FNL may include the plurality of sub-adhesive layers AL-a, AL-b, and AL-c and the plurality of sub-functional layers FNL-a, FNL-b, FNL-c, and PF.

In an embodiment illustrated in FIG. 10A, the functional layer FNL may be the reflection preventing layer. When the functional layer FNL is the reflection preventing layer, the first sub-functional layer FNL-a disposed on the electronic panel EP and the second sub-functional layer FNL-b disposed on the first sub-functional layer FNL-a may be phase retarders. The first sub-functional layer FNL-a may be a λ/4 phase retarder, and the second sub-functional layer FNL-b may be a λ/2 phase retarder. When the functional layer FNL is the reflection preventing layer, the third sub-functional layer FNL-c disposed on the second sub-functional layer FNL-b may be a polarizing film and may include a polyvinyl alcohol film. The plurality of sub-adhesive layers AL-a, AL-b, and AL-c may be arranged between the electronic panel EP, the first sub-functional layer FNL-a, the second sub-functional layer FNL-b, and the third sub-functional layer FNL-c.

The functional layer FNL may include a base layer PF as a sub-functional layer. The base layer PF may be disposed on the third sub-functional layer FNL-c and may support and protect the sub-functional layers arranged below. The base layer PF may include, for example, a cycle-olefin polymer (COP).

The hydrophilic coating part HCP is disposed on a side surface of the main part MP. The hydrophilic coating part HCP is disposed between the main part MP and the bending protecting layer BPL. The hydrophilic coating part HCP may be disposed on side surfaces of at least some of the plurality of sub-adhesive layers AL-a, AL-b, and AL-c and the plurality of sub-functional layers FNL-a, FNL-b, FNL-c, and PF included in the main part MP. As illustrated in FIG. 10A, the hydrophilic coating part HCP may be disposed on side surfaces of all of the plurality of sub-adhesive layers AL-a, AL-b, and AL-c and the plurality of sub-functional layers FNL-a, FNL-b, FNL-c, and PF included in the main part MP.

The hydrophilic coating part HCP may include a hydrophilic material and thus have high surface energy. The hydrophilic coating part HCP may include a material having higher surface energy than that of the bending protecting layer BPL. The hydrophilic coating part HCP may include a material having higher surface energy than that of the main part MP. The hydrophilic coating part HCP may include an inorganic material or an organic material having a hydrophilic functional group. For example, the hydrophilic coating part HCP may include silica having a hydroxy group as a hydrophilic material. However, the present disclosure is not limited thereto, and the hydrophilic material included in the hydrophilic coating part HCP is not limited as long as the material that may be coated on a side surface of the main part MP and has hydrophilic properties.

The hydrophilic coating part HCP may be disposed adjacent to the bending protecting layer BPL compared to the main part MP, and a side surface of the hydrophilic coating part HCP, which is adjacent to the bending protecting layer BPL, may define the first side surface FNL-L. As the hydrophilic coating part HCP includes a hydrophilic material having high surface energy, the bending protecting layer BPL including a hydrophobic material having relatively low surface energy is spaced the predetermined distance GV from the hydrophilic coating part HCP. That is, the first side surface FNL-L provided in the hydrophilic coating part HCP and the second side surface BPL-L of the bending protecting layer BPL may be spaced apart from each other.

As the hydrophilic coating part HCP is disposed on the side surfaces of all of the plurality of sub-adhesive layers AL-a, AL-b, and AL-c and the plurality of sub-functional layers FNL-a, FNL-b, FNL-c, and PF included in the main part MP, a thickness h1 of the main part MP and a thickness h3 of the hydrophilic coating part HCP may be substantially the same. In the specification, the fact that the thicknesses are "substantially the same" includes a case in which the thicknesses are physically the same as well as a case in which there is a difference between the thicknesses, which is equivalent to an error that may occur in a process despite the same design.

The thickness h1 of the main part MP included in the functional layer FNL may be greater than or equal to a thickness h2 of the bending protecting layer BPL. FIG. 10A illustrates that the thickness h1 of the main part MP and the thickness h2 of the bending protecting layer BPL are substantially the same, but the present disclosure is not limited thereto, and the thickness h2 of the bending protecting layer BPL may be smaller than the thickness h1 of the main part MP. In the display device according to an embodiment, as the hydrophilic coating part HCP is provided in the functional layer FNL, in a process of forming the bending protecting layer BPL, a material forming the bending protecting layer BPL may be prevented from overflowing onto an upper side of the functional layer FNL, and thus the thickness h2 of the bending protecting layer BPL may not be greater than the thickness h1 of the main part MP included in the functional layer FNL.

An upper surface of the hydrophilic coating part HCP and an upper surface of the main part MP may be aligned with each other. The upper surface of the hydrophilic coating part HCP and the upper surface of the main part MP may provide one parallel alignment surface without a step difference. As the upper surface of the hydrophilic coating part HCP and the upper surface of the main part MP are aligned with each other, the overflowing of the material forming the bending protecting layer BPL to a portion in which the main part MP is disposed in the process of forming the bending protecting layer BPL may be effectively blocked by the hydrophilic coating part HCP.

In the display device of an embodiment, the functional layer FNL disposed on the display panel may include the hydrophilic coating part HCP disposed adjacent to the bending protecting layer BPL, and thus the material forming the bending protecting layer BPL may be prevented from overflowing onto the upper side of the functional layer FNL in the process of forming the bending protecting layer BPL.

Unlike the present disclosure, when the bending protecting layer BPL is formed higher than the functional layer FNL because the functional layer FNL does not include the hydrophilic coating part HCP, an adhesive layer such as the second adhesive layer AL2 (see FIG. 7) disposed on the upper side should be formed to be thick to compensate for a step difference of the high bending protecting layer BPL, and the OCA or the like having low hardness should be used to form the second adhesive layer AL2 to be thick. In this case, as the OCA having low hardness is applied, there is a possibility that moisture and oxygen may penetrate into the display device increases, and a possibility that wave-shaped defects may occur in the display device due to external pressure increases.

In the display device according to an embodiment of the present disclosure, as the hydrophilic coating part HCP is provided in the functional layer FNL, the bending protecting layer BPL may be spaced a predetermined distance from at least a portion of the functional layer FNL without contact through a surface energy difference in the process of forming the bending protecting layer BPL through a hydrophobic bending protecting resin. Accordingly, the material forming the bending protecting layer BPL may be prevented from overflowing onto the upper side of the functional layer FNL, it is not necessary to form a thick adhesive layer such as the second adhesive layer AL2 (see FIG. 7) disposed on the upper side due to the step difference of the bending protecting layer BPL, and thus the second adhesive layer AL2 may be formed through the OCA having high hardness. Accordingly, durability of the display device may be improved.

Referring to FIG. 10B, unlike the illustration in FIG. 10A, a hydrophilic coating part HCP-1 included in a functional layer FNL-1 may be disposed on a side surface of a main part MP-1 and may be disposed only on side surfaces of some of the plurality of sub-adhesive layers AL-a, AL-b, and AL-c and the plurality of sub-functional layers FNL-a, FNL-b, FNL-c, and PF included in the main part MP-1. For example, as illustrated in FIG. 10B, the hydrophilic coating part HCP-1 may be disposed on side surfaces of the third sub-functional layer FNL-c and the base layer PF and may not be disposed on side surfaces of the first sub-functional layer FNL-a, the second sub-functional layer FNL-b, and the plurality of sub-adhesive layers AL-a, AL-b, and AL-c. Even when the hydrophilic coating part HCP-1 is disposed only on a side surface of at least a portion of the main part MP-1, the hydrophilic coating part HCP-1 may be disposed at least on a side surface of at an uppermost layer among the plurality of layers included in the main part MP-1. For example, in FIGS. 10A and 10B, an uppermost sub-functional layer of the main part MP-1 included in the functional layer FNL or FNL-1 may be the base layer PF, and the hydrophilic coating part HCP or HCP-1 may be disposed at least on a side surface of the base layer PF.

Referring back to FIG. 10B, as the hydrophilic coating part HCP-1 is disposed only on side surfaces of at least some of the plurality of layers included in the main part MP-1, the thickness h1 of the main part MP-1 may be greater than a thickness h3’ of the hydrophilic coating part HCP-1. Even when the thickness h3’ of the hydrophilic coating part HCP-1 is smaller than the thickness h1 of the main part MP-1, an upper surface of the hydrophilic coating part HCP-1 and an upper surface of the main part MP-1 are aligned with each other, and thus in the process of forming the bending protecting layer BPL, the overflowing of the material forming the bending protecting layer BPL to a portion in which the main part MP-1 is disposed may be prevented by the hydrophilic coating part HCP-1.

The hydrophilic coating part HCP-1 may be disposed adjacent to the bending protecting layer BPL compared to the main part MP-1, a portion of the main part MP-1, in which the hydrophilic coating part HCP-1 is not disposed, may define a (1-1)^{th} side surface FNL-L1, and a side surface of the hydrophilic coating part HCP-1, which is adjacent to the bending protecting layer BPL, may define a (1-2)^{th} side surface FNL-L2. As the hydrophilic coating part HCP-1 includes a hydrophilic material having high surface energy, the bending protecting layer BPL including a hydrophobic material having relatively low surface energy is spaced the predetermined distance GV from the hydrophilic coating part HCP-1. As the hydrophilic coating part HCP-1 is disposed only on a side surface of a portion of the main part MP-1, a lower portion of the bending protecting layer BPL may be in contact with the functional layer FNL-1. That is, a lower portion of the second side surface BPL-L of the bending protecting layer BPL may be in contact with the (1-1)^{th} side surface FNL-L1 of the functional layer FNL-1, and the (1-2)^{th} side surface FNL-L2 provided in the hydrophilic coating part HCP-1 and the remainder of the second side surface BPL-L may be spaced apart from each other to provide the predetermined distance GV.

Referring to FIG. 10C, unlike the illustration of FIG. 10A, a functional layer FNL-2 may be an impact absorbing layer, and a main part MP’ may include a flexible resin layer DLL for absorbing an impact. The flexible resin layer DLL may be attached onto the electronic panel EP by the sub-adhesive layer AL-a. The flexible resin layer DLL may include a polyimide (PI) or polyethylene terephthalate (PET) material for absorbing an impact.

A hydrophilic coating part HCP-2 is disposed on a side surface of the main part MP’. The hydrophilic coating part HCP-2 is disposed between the main part MP’ and the bending protecting layer BPL. The hydrophilic coating part HCP-2 may be disposed on a side surface of at least some of the sub-adhesive layer AL-a and the flexible resin layer DLL included in the main part MP’. As illustrated in FIG. 10C, the hydrophilic coating part HCP-2 may be disposed on side surfaces of all of the sub-adhesive layer AL-a and the flexible resin layer DLL included in the main part MP’. However, the present disclosure is not limited thereto, and the hydrophilic coating part HCP-2 may be disposed only on the side surface of the flexible resin layer DLL, which is an uppermost functional layer of the main part MP’, and may not be disposed on the side surface of the sub-adhesive layer AL-a.

The hydrophilic coating part HCP-2 may be disposed adjacent to the bending protecting layer BPL compared to the main part MP’, and a side surface of the hydrophilic coating part HCP-2, which is adjacent to the bending protecting layer BPL, may define the first side surface FNL-L. As the hydrophilic coating part HCP-2 includes a hydrophilic material having high surface energy, the bending protecting layer BPL including a hydrophobic material having relatively low surface energy is spaced the predetermined distance GV from the hydrophilic coating part HCP-2. That is, the first side surface FNL-L provided in the hydrophilic coating part HCP-2 and the second side surface BPL-L of the bending protecting layer BPL may be spaced apart from each other. In the display device of an embodiment, the functional layer FNL-2 disposed on the display panel may include the hydrophilic coating part HCP-2 disposed adjacent to the bending protecting layer BPL, and thus in the process of forming the bending protecting layer BPL, the material forming the bending protecting layer BPL may be prevented from overflowing onto an upper side of the flexible resin layer DLL included in the functional layer FNL-2.

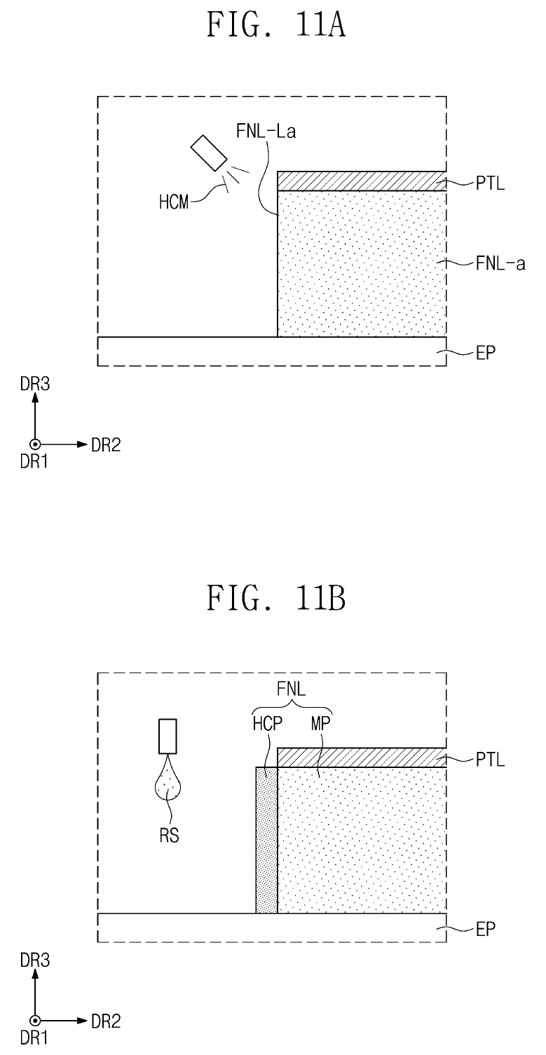

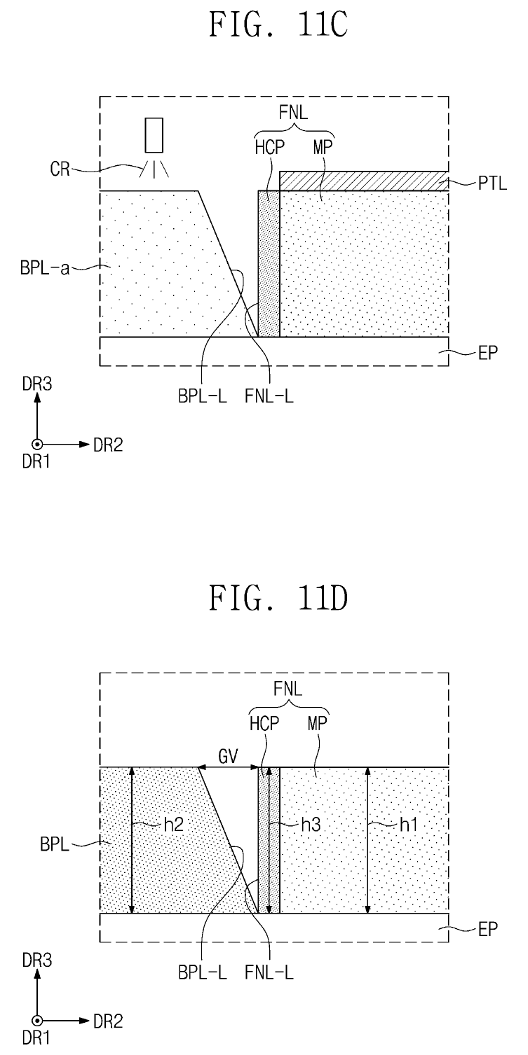

Hereinafter, a method of manufacturing a display device according to an embodiment will be described with reference to FIGS. 11A to 11D. In the description of the method of manufacturing a display device according to an embodiment with reference to FIGS. 11A to 11D, contents duplicated with the description of the display device according to an embodiment with reference to FIGS. 1 to 10C will not be described again and differences therebetween will be mainly described.

FIGS. 11A to 11D are schematic views illustrating some of operations of a method of manufacturing a display device according to an embodiment. FIGS. 11A to 11D illustrate cross sections of operations of the manufacturing method in area BB’ illustrated in FIG. 10A or the like, and the operations of the method of manufacturing a display device according to an embodiment, which are illustrated in FIGS. 11A to 11D, may be sequentially performed operations.

The method of manufacturing a display device according to an embodiment includes an operation of providing a display panel, an operation of providing a preliminary functional layer on the display panel, an operation of forming a hydrophilic coating part by providing a hydrophilic material onto one side of the preliminary functional layer, and an operation of forming a bending protecting layer by providing and curing a bending protecting resin in a bending area.

Referring to FIG. 11A, the method of manufacturing a display device according to an embodiment includes an operation of providing a preliminary functional layer FNL-a on the electronic panel EP after providing the electronic panel EP including the display panel DP (see FIG. 4A). The preliminary functional layer FNL-a may correspond to the main part MP, MP-1, or MP′ of the functional layer described in FIGS. 10A to 10C. That is, the preliminary functional layer FNL-a may correspond to a portion of the functional layer, in which the hydrophilic coating part is not formed, according to an embodiment.

A protective film PTL may be formed on the preliminary functional layer FNL-a. The protective film PTL may be formed on the preliminary functional layer FNL-a before the operation of forming the hydrophilic coating part. The protective film PTL may be provided to protect the preliminary functional layer FNL-a for forming a reflection preventing layer or an impact absorbing layer in a process of manufacturing a display device.

Referring to FIGS. 11A and 11B, the method of manufacturing a display device according to an embodiment includes the operation of forming the hydrophilic coating part HCP by providing a hydrophilic material HCM onto one side surface FNL-La of the preliminary functional layer FNL-a. The hydrophilic coating part HCP may be formed of the hydrophilic material HCM having a higher surface energy than that of a material included in the preliminary functional layer FNL-a. The hydrophilic material HCM may include, for example, an inorganic material or an organic material having a hydrophilic functional group. For example, the hydrophilic material HCM may include silica having a hydroxy group. After the hydrophilic coating part HCP is formed of the hydrophilic material HCM, the main part MP may be formed in correspondence to the existing preliminary functional layer FNL-a, and the functional layer FNL including the main part MP and the hydrophilic coating part HCP may be formed.

Referring to FIGS. 11B and 11C, a preliminary bending protecting layer BPL-a may be formed by providing a bending protecting resin RS to at least the bending area BA (see FIG. 9) after the hydrophilic coating part HCP is formed. The bending protecting resin RS may include an epoxy-based resin, an acryl-based resin, a urethane-based resin, or a urethane acrylate-based resin. For example, the bending protecting resin RS may include an acryl-based resin or a urethane-based resin. The bending protecting resin RS may be provided on the electronic panel EP through a nozzle or the like.

The bending protecting resin RS before curing has flowability so that a portion adjacent to the functional layer FNL may also be coated. However, the functional layer FNL includes the hydrophilic coating part HCP formed of the hydrophilic material HCM, and thus the bending protecting resin RS does not flow to the upper side of the functional layer FNL. Accordingly, the preliminary bending protecting layer BPL-a may be spaced the predetermined distance GV from the functional layer FNL.

Referring to FIGS. 11C and 11D together, the preliminary bending protecting layer BPL-a may be cured CR to form the bending protecting layer BPL. As described above, the preliminary bending protecting layer BPL-a may be spaced the predetermined distance GV from the functional layer FNL by the hydrophilic coating part HCP, and thus the bending protecting layer BPL formed by curing the preliminary bending protecting layer BPL-a may be spaced the predetermined distance GV from the functional layer FNL. That is, the first side surface FNL-L provided in the hydrophilic coating part HCP and the second side surface BPL-L of the bending protecting layer BPL may be spaced apart from each other. After the preliminary bending protecting layer BPL-a is cured CR to form the bending protecting layer BPL, the protective film PTL may be removed.

Unlike in the above described embodiment, when the hydrophilic coating part HCP is not formed, the bending protecting resin RS may flow to a side surface of the protective film PTL disposed on the functional layer FNL, and the preliminary bending protecting layer BPL-a and the bending protecting layer BPL formed by curing the preliminary bending protecting layer BPL-a may be thicker than the functional layer FNL. In a subsequent process, when the protective film PTL is removed, an adhesive layer such as a second adhesive layer (AL2, FIG. 7) disposed on the upper side should be formed to be thick to compensate for the step difference of the thick bending protecting layer BPL, and thus the OCA having low hardness may be applied to reduce the durability of the display device.

In the method of manufacturing a display device according to an embodiment of the present disclosure, since the hydrophilic coating part HCP is formed on one side of the functional layer FNL adjacent to the bending area, in a process of forming the bending protecting layer BPL thereafter, the bending protecting layer BPL may be spaced a predetermined distance from at least a portion of the functional layer FNL without contact through a surface energy difference from the hydrophilic coating part HCP. Accordingly, the material forming the bending protecting layer BPL may be prevented from overflowing onto the upper side of the functional layer FNL, it is not necessary to form a thick adhesive layer such as the second adhesive layer AL2 (see FIG. 7) disposed on the upper side due to the step difference of the bending protecting layer BPL, and thus the second adhesive layer AL2 may be formed through the OCA having high hardness. Thus, the durability of the display device manufactured through the manufacturing method according to an embodiment may be improved.

In a display device and an electronic device including the same according to an embodiment, a possibility that moisture and oxygen penetrate into the device may be reduced, wave-shaped defects may be prevented from occurring in the display device due to an external pressure, and thus durability and reliability may be improved.

A method of manufacturing a display device according to an embodiment may provide a display device having excellent durability and reliability.

Although the description has been made above with reference to an embodiment of the present disclosure, those skilled in the art may understand that the present disclosure may be variously modified and changed without departing from the spirit and the technical scope of the present disclosure described in the appended claims.

Thus, the technical scope of the present disclosure should not be limited to the contents described in the detailed description of the specification but should be defined by the appended claims.

What is claimed is:

1. A display device comprising:
a display panel including a first area and a bending area adjacent to the first area, the bending area having a predetermined radius of curvature;
a functional layer disposed on the display panel and overlapping the first area; and
a bending protecting layer disposed on the display panel, wherein at least a portion of the bending protecting layer overlaps the bending area on a plane,
wherein the functional layer includes:
a main part overlapping the first area; and
a hydrophilic coating part disposed between the main part and the bending protecting layer, and
wherein the at least a portion of the bending protecting layer is spaced a predetermined distance from the hydrophilic coating part.

2. The display device of claim 1, wherein the functional layer is a reflection preventing layer.

3. The display device of claim 2, wherein the main part includes at least one sub-adhesive layer disposed on the display panel and at least one sub-functional layer disposed on the at least one sub-adhesive layer.

4. The display device of claim 3, wherein the sub-functional layer includes an uppermost sub-functional layer disposed on an uppermost side of the main part, and
wherein the hydrophilic coating part is disposed on at least a side surface of the uppermost sub-functional layer.

5. The display device of claim 1, wherein a thickness of the hydrophilic coating part is substantially the same as a thickness of the main part.

6. The display device of claim 1, wherein a thickness of the hydrophilic coating part is smaller than a thickness of the main part.

7. The display device of claim 1, wherein the display panel includes a base layer, a circuit layer disposed on the base layer, and a light emitting element layer disposed on the circuit layer, and
wherein the functional layer is disposed on the light emitting element layer.

8. The display device of claim 1, wherein an upper surface of the hydrophilic coating part and an upper surface of the main part are aligned with each other.

9. The display device of claim 1, wherein the functional layer is an impact absorbing layer.

10. The display device of claim 1, further comprising:
a window disposed on the functional layer.

11. The display device of claim 1, wherein a thickness of the functional layer is greater than or equal to a thickness of the bending protecting layer.

12. The display device of claim 1, wherein the hydrophilic coating part includes a material having higher surface energy than a surface energy of the bending protecting layer.

13. An electronic device comprising:
a display panel including a first area, a second area, and a bending area disposed between the first area and the second area, the bending area having a predetermined radius of curvature;
a functional layer which is disposed on the display panel and of which at least a portion overlaps the first area on a plane; and
a bending protecting layer disposed on the display panel, wherein at least a portion of the bending protection layer overlaps the bending area on a plane,
wherein the functional layer includes:
a main part overlapping the first area and including at least one sub-adhesive layer and at least one sub-functional layer; and
a hydrophilic coating part disposed between the main part and the bending protecting layer.

14. The electronic device of claim 13, further comprising:
a printed circuit board electrically connected to the second area of the display panel.

15. The electronic device of claim 13, wherein an upper surface of the hydrophilic coating part and an upper surface of the main part are aligned with each other.

16. The electronic device of claim 13, wherein the display panel further includes pixels overlapping the first area on a plane and a driving part overlapping the second area and connected to the pixels on a plane.

17. A method of manufacturing a display device, the method comprising:
providing a display panel including a first area and a bending area adjacent to the first area;
providing a preliminary functional layer on the display panel such that the preliminary functional layer overlaps the first area on a plane;
forming a hydrophilic coating part by providing a hydrophilic material onto one side of the preliminary functional layer adjacent to the bending area; and
forming a bending protecting layer by providing a bending protecting resin to the bending area and curing the bending protecting resin in the bending area,
wherein at least a portion of the bending protecting layer is spaced a predetermined distance from the hydrophilic coating part.

18. The method of claim 17, wherein, providing the preliminary functional layer includes providing a protective film is on the preliminary functional layer, and
wherein the method further comprises removing the protective film after forming the bending protecting layer.

19. The method of claim 17, wherein, forming of the hydrophilic coating part includes forming a functional layer having a main part overlapping the first area and the hydrophilic coating part, and
wherein forming the main part includes forming at least one sub-adhesive layer disposed on the display panel and at least one sub-function layer disposed on the at least one sub-adhesive layer.

20. The method of claim 19, wherein, after forming the hydrophilic coating part, an upper surface of the hydrophilic coating part and an upper surface of the main part are aligned with each other.
